(19) United States
(12) Patent Application Publication
(10) Pub. No.: US 2026/0053073 A1
(43) Pub. Date: Feb. 19, 2026

(54) SUPER AI DEVICE BY STITCHING TECHNIQUES

(71) Applicant: Taiwan Semiconductor Manufacturing Co., Ltd., Hsinchu (TW)

(72) Inventors: Chih-Chao CHOU, Hsinchu (TW); Yi-Hsun CHIU, Hsinchu (TW); Chih-Hao WANG, Hsinchu (TW); Che-Yi LIN, Hsinchu (TW); Ching-Wei TSAI, Hsinchu (TW)

(21) Appl. No.: 19/008,220

(22) Filed: Jan. 2, 2025

Related U.S. Application Data
(60) Provisional application No. 63/684,809, filed on Aug. 19, 2024.

(51) Int. Cl. H01L 23/498; H01L 23/544

(52) U.S. Cl. CPC H01L 23/49816; H01L 23/544; H01L 2223/54426

(57) ABSTRACT

A structure includes a combinational semiconductor die, an interposer, and solder bumps coupled between the combinational semiconductor die and the interposer. The combinational semiconductor die includes a first unit region and a second unit region over a semiconductor substrate. The first unit region abuts the second unit region. The first unit region includes a first device portion and a first dummy portion. The second unit region includes a second device portion and a second dummy portion The first dummy portion includes a first conductive feature and the second dummy portion includes a second conductive feature in physical contact with the first conductive feature.

### BACKGROUND

Improvements to the packaging of components seek to provide smaller packages that occupy less area than previous packages. Examples of the type of packages for semiconductors include quad flat pack (QFP), pin grid array (PGA), ball grid array (BGA), flip chips (FC), three-dimensional integrated circuits (3DICs), wafer level packages (WLPs), package on package (POP), System on Chip (SoC) or System on Integrated Circuit (SoIC) devices. Some of these three-dimensional devices (e.g., 3DIC, SoC, SoIC) are prepared by placing chips over chips on a semiconductor wafer level. These three-dimensional devices provide improved integration density and other advantages, such as faster speeds and higher bandwidth due to the decreased length of interconnects between the stacked chips. However, there are many challenges related to three-dimensional devices.

For example, in the packaging of integrated circuits, a plurality of device dies may be bonded on an interposer wafer, which may include a plurality of interposers disposed therein. After bonding the device dies, an underfill is dispensed to fill gaps between the device dies and the interposer wafer. A curing process may then be performed to cure the underfill. A molding compound can be applied to encapsulate the device dies. The resulting interposer wafer and top dies may then be sawed apart into a plurality of packages, with the packages including exposed electrical connectors (e.g., solder balls). The packages are then bonded to package substrates or printed circuit boards.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a top view of a combinational semiconductor die in accordance with some embodiments.

FIG. 2 illustrates a cross-sectional view of a package including a combinational semiconductor die, in accordance with some embodiments.

FIG. 3 shows in a cross-sectional view, dummy portions of a combinational semiconductor die, accordance with some embodiments

FIGS. 4A-4J show a structure in various stages of a process, in accordance with some embodiments.

FIG. 5 shows a flow chart of a process, in accordance with some embodiments.

FIGS. 6-8 show some example implementations.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of the present disclosure are directed to a base or interconnection device die and to interconnection structures with additional dies connected therewith, such as a system on integrated chip (SoIC) packaging design and structure.

The massive scale of modern data, such as analytics data or AI programming, easily overwhelms memory and computation resources on computational servers. For example, deriving meaningful insights from big data requires rich analytics. The big data and AI sectors demand ever increasing throughput to extraordinary large volumes of data. This is true both with respect to the exponential rise in the volume of data itself and to the increasing number and complexity of formats of data that such platforms must manage. AI and big data chipsets today are required to manage not just relational data, but also text, video, image, emails, social network feeds, real time data streams, sensor data, etc.

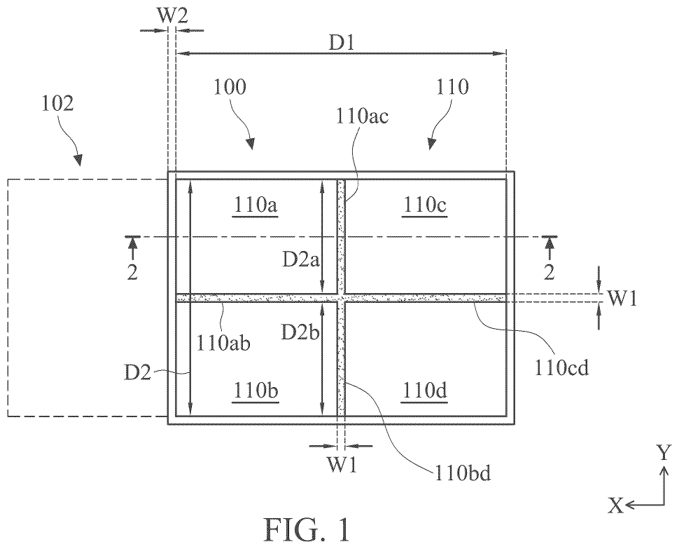

FIG. 1 schematically illustrates a top view of a combinational semiconductor die 100 in accordance with some embodiments. Semiconductor die 100 may include two or more unit dies or unit die regions (“unit regions”) 110. Four unit regions 110a, 110b, 110c, 110d are shown as an illustrative example in FIG. 1. In some implementations, the unit regions 110a, 110b, 110c, and 110d include similar dimensions, similar circuitry structures, and similar functional blocks. For example, each of the unit regions 110 includes graphics processing unit “GPU” circuitry for super artificial intelligence “AI” applications. In some implementations, one or more unit regions 110 include different dimensions, different circuitry structures, or different functional blocks from other unit regions 110 in the combinational semiconductor die 100. For example, in some implementations, one or more unit regions 110 are memory chips and one or more unit regions 110 are AI GPU chips.

A stitching zone 110ab is disposed between unit region 110a and unit region 110b, and includes respective dummy portions of each of unit region 110a and unit region 110b. A stitching zone 110ac is disposed between unit region 110a and unit region 110c, and includes respective dummy portions of each of unit region 110a and unit region 110c. A stitching zone 110bd is disposed between unit region 110b and unit region 110d, and includes respective dummy portions of each of unit region 110b and unit region 110d. A stitching zone 110cd is disposed between unit region 110c and unit region 110d, and includes respective dummy portions of unit region 110c and unit region 110d. In some implementations, a dummy portion does not include the functional blocks or circuitry of the corresponding unit region 110, although the dummy portion includes features that function to “stitch” or join the adjacent unit regions 110. For example, the dummy portions each includes alignment marks and conductive or metal features. The metal features connect circuitry of adjacent unit regions 110. The alignment marks function to, among others, align the metal features of adjacent dummy portions in the formation of the adjacent unit regions 110.

The stitching zones each includes respective dummy portions of the adjacent unit regions 110 and thus overlays partially each of the adjacent unit regions 110. The stitching zones are disposed within the combinational semiconductor die 100 and is referred to as “in-chip overlay” zone for descriptive purposes and to differentiate from overlay regions that are formed outside and between two dies or chips. Portions of the unit regions other than the dummy portions are referred to as “device portions.” A device portion of a unit region include the semiconductor devices, e.g., transistors, that form the functional blocks of the unit region. The device portion may include a variety of devices formed thereon. For example, the variety of devices may include active components, passive components, or a combination thereof. For example, the device portion may include circuit components that form a memory array or other memory structures. For example, the device portion may include circuit components that provide functionality blocks such as communication, logic, graphics, general processing, or other data processing functions. In some embodiments, the device portion may include GPUs for super AI applications.

The stitching zones 110ab, 110ac, 110bd, 110cd each includes a width W1. In some implementations, the width W1 is in a range from about 10 μm to about 40 μm, inclusive. For example, the width W1 is about 20 μm. The physical distance W2 between the combinational semiconductor die 100 and an adjacent semiconductor die 102 (shown in dotted block in FIG. 1), cither a combinational semiconductor die or a unit semiconductor die, e.g., having only 1 unit of device portion, is in a range from about 40 μm to about 300 μm. In some implementations, the combinational semiconductor die 100 and the adjacent semiconductor die 102 are both positioned on an interposer die (“interposer”) or on a package substrate (not shown in FIG. 1). Due to the physical design rules or restrictions, e.g., the space margin for die handling or the solder bump or solder ball spacing, the physical distance W2 cannot be unlimitedly reduced such that the width W1 of the stitching zones will always be able to be smaller than the physical distance W2 between adjacent semiconductor dies positioned on an interposer or a package substrate.

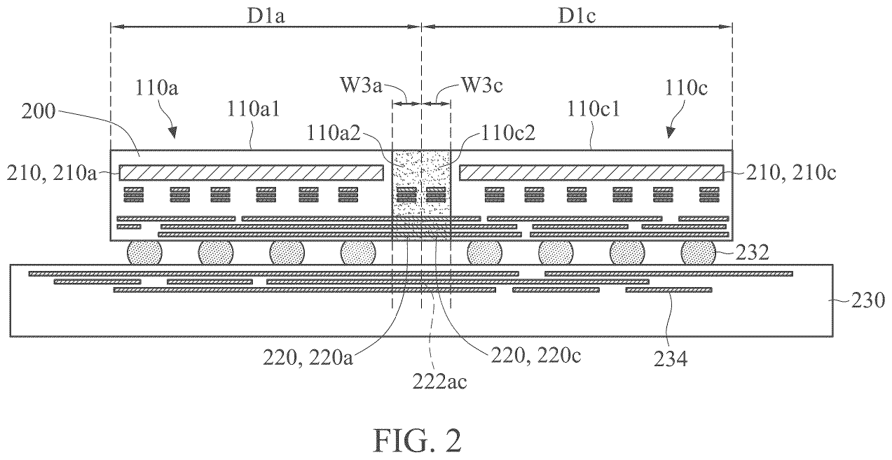

FIG. 2 illustrates a cross-sectional view of a package structure 201 including the combinational semiconductor die 100 from cross-sectional line 2-2 shown in FIG. 1. In accordance with some implementations of the present disclosure, each of the unit regions 110a, 110c includes a respective device portion 110a1, 110cl and a respective dummy portion 110a2, 110c2. The dummy portions 110a2, 110c2 are adjacent to one another. In some implementations, the dummy portions 110a2, 110c2 abut one another. The device portions 110a1, 110cl each includes integrated circuit devices 210 (210a, 210c), which are formed on a semiconductor substrate 200. Representative integrated circuit devices 210 include complementary metal-oxide semiconductor (CMOS) transistors, resistors, capacitors, diodes, or the like. Details of integrated circuit devices 210 are not illustrated herein. In some implementations of the present disclosure, integrated circuit devices 210 are graphics processing units.

In some implementations, the dummy portions 110a2, 110c2 each does not include active devices such as transistors or diodes, and may or may not include passive devices. The dummy portions 110a2, 110c2 may include conductive features 220 (220a, 220c), e.g., metal pads or lines, arranged in a metallization level or on multiple metallization levels. Conductive traces and vias may also be formed in each of the dummy portions 110a2, 110c2, which electrically interconnect conductive features on different metallization levels.

The substrate 200 may be a semiconductor substrate or a dielectric substrate. In the case of substrate 200 including a semiconductor substrate, substrate 200 may be formed of crystalline silicon, crystalline germanium, silicon germanium, or a III-V compound semiconductor, such as GaAsP, AlInAs, AlGaAs, GaInAs, GaInP, GaInAsP, or the like. Semiconductor substrate 200 may also be a bulk silicon substrate or a silicon-on-insulator (SOI) substrate. Shallow trench isolation (STI) regions (not illustrated) may be formed in semiconductor substrate 200 to isolate active regions in semiconductor substrate 200. In the case of substrate 200 including a dielectric substrate, substrate 200 may be formed of silicon oxide, silicon carbide, silicon nitride, or the like. Through-vias (not illustrated) may be formed to extend into semiconductor substrate 200, where through-vias are used to electrically inter-couple features on opposite sides of semiconductor die boo. Through-vias may be insulated from substrate 200 by isolation layers.

Referring to FIGS. 1 and 2 together, in some implementations, unit regions 110a and 110c each have a size as limited by the applicable reticle size limitation, e.g., 26 mm×33 mm. The combinational semiconductor die 100 integrates or combines two or more unit regions of full reticle size limitations arranged with respect to one another in at least one direction. As shown in FIG. 1 as an example, the combinational semiconductor die 100 integrates or combines four unit regions each of a size of full reticle size limitations, which are arranged in two directions, x-axis and y-axis directions. The dimensions D1 of the combinational semiconductor die 100 in the x-axis equals to the addition of the corresponding dimensions D1a, D1c of the unit regions 110a, 110c adjacent to one another in the x-axis. In some implementations, dimensions D1a, D1c of the unit regions 110a, 110c are each substantially 33 mm, which is the full reticle size limitation in the x-axis (or y-axis) direction. The dimensions D2 of the combinational semiconductor die 100 in the y-axis equals to addition of the corresponding dimensions D2a, D2b of the unit regions 110a, 110b adjacent to one another in the y-axis. In some implementations, dimensions D2a, D2b of the unit regions 110a, 110b are each substantially 26 mm, which is the full reticle size limitation in the y-axis (or x-axis) direction. As such, dimension D1 of the combinational semiconductor die 100 is substantially 66 mm, and dimension D2 of the combinational semiconductor die 100 is substantially 52 mm. Note that the full reticle size limitations illustrated herein are based on the current i193 and EUV lithography steppers, which have a maximum field size of 26 mm by 33 mm or 858 mm². The full reticle size or the size of the unit regions 110 may change with different lithography steppers. For example, with High-NA EUV lithography steppers, the reticle limitation will be 26 mm by 16.5 mm or 429 mm² due to the use of anamorphic lens array.

The dummy portions 110a2, 110b2, 110c2, 110d2 are included in the corresponding unit regions 110a, 110b, 110c, 110d. The full reticle dimensions of a unit region include that of the dummy portion(s) of the unit region. If a unit region 110 is adjacent to more than one adjacent unit regions, it may include more than one dummy portions adjacent to each of the adjacent unit region 110. The dummy portion 110a2 includes a width W3a in the x-axis along which the unit region 110a is adjacent to the unit region 110c, and the dummy portion 110c2 includes a width W3c in the x-axis along which the unit region 110a is adjacent to the unit region 110c. The width of a dummy portion in a direction that the dummy region or its unit region is adjacent to an adjacent unit region, e.g., W3a, W3c, is in a range from about 5 μm to about 20 μm. In some implementations, adjacent dummy portions, e.g., 110a2 and 110c2, have substantially a same width. In some implementations, adjacent dummy portions, e.g., 110a2 and 110c2, have different widths. In some implementations, dummy portions in a same unit region 110, if the unit region 110 includes multiple dummy portions, includes a same width in the respective directions along which each is adjacent to an adjacent unit region. In some implementations, dummy portions in a same unit region 110 may have different widths.

Two adjacent dummy portions, e.g., 110a2, 110c2, function together to connect the active devices in the corresponding device portions 110a1, 110c1. The two dummy portions 110a2, 110c2 abut one another and thus form an stitching zone 110ac, which includes metal features 220 that extend from unit region 110a to unit region 110c. The metal feature 220 includes metal features 220a in the dummy portion 110a2 and metal features 220c in the dummy portion 110c2. The metal features 220a, 220c are stitched or joined together at a border line 222ac between the unit region 110a and unit region 110c.

In some implementations, a stitching zone is a strip, which may have a uniform width. In some implementations, the strip-sized stitching region extends from a first side of a unit region, e.g., 110a, to a second side of the unit region along a direction, e.g., y-axis direction, that crosses a direction, e.g., x-axis direction, along which the corresponding two unit regions, e.g., 110a, 110c, are arranged with respect to one another.

In some implementations, adjacent unit regions 110a, 110c may have a substantially same size, although in some implementations, their sizes or shapes may be different from each other.

Regions 110B and 110D have an stitching zone 110BD. Metal features that extend from region 110B to region 110D are stitched together in region 110BD. In an embodiment, stitching zone 110BD is a strip, which may have a uniform width. Additionally, regions 110B and 110D may have a substantially same size or shape; although in other embodiments, their sizes and shapes may be different from each other.

The semiconductor package structure 201 may include one or more combinational semiconductor dies each including a plurality of unit regions and stitching zones between adjacent unit regions. The semiconductor package structure 201 may also include one or more or unit semiconductor dies each being similar to a unit region in a combinational semiconductor die with or without a dummy portion. The combinational semiconductor dies and/or the unit semiconductor dies may be positioned on an interposer 230 or a package substrate. The semiconductor dies are electrically coupled to the interposer 230 through coupling features like solder bumps 232. The interposer 230 may include redistribution RDL layers 234 adjacent to the coupling features 232. For example, the RDL layers 234 of the interposer 230 may include 3-5 layers each with a pitch about 720 nm. Details of the package structure 201 will be further provided herein.

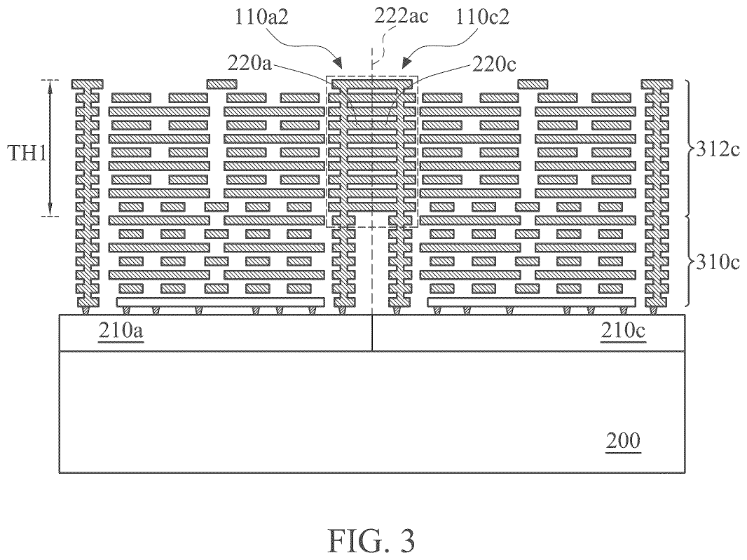

FIG. 3 shows, in a cross-sectional view, details of example dummy portions 110a2, 110c2. As shown in FIG. 3, devices 210a, 210c, e.g., GPU devices, are formed on the substrate 200. Inter-layer dielectric (ILD) is formed over semiconductor substrate 200.

The dummy portions 110a2, 110c2 are formed as parts of the back-end-of-line BEOL metallization structure over the devices 210a, 210c, respectively. The BEOL structure includes lower metallization levels 310 and redistribution levels 312 over the lower metallization levels 310. The BEOL structure, shown as lower metallization levels 310 and redistribution levels 312, may include an inter-layer dielectric (ILD) and one or more inter-metal dielectric (IMD) layers (not specifically shown for brevity), various metal features (e.g., wires, interconnection features, metal patterns) including conductive features 220 (220a, 220c) of the dummy portions 110a2, 110c2, and one or more passivation layers. In some embodiments, the ILD may be formed of a dielectric material such as silicon oxide (SiO2) silicon nitride (SiN or Si3N4), silicon carbide (SiC), or the like, and may be deposited by any suitable deposition process. Herein, “suitable deposition processes” may include a chemical vapor deposition (CVD) process, a physical vapor deposition (PVD) process, an atomic layer deposition (ALD) process, a high density plasma CVD (HDPCVD) process, a low pressure CVD process, a metalorganic CVD (MOCVD) process, a plasma enhanced CVD (PECVD) process, a sputtering process, laser ablation, or the like.

The IMD layers may include an extra low-k (ELK) dielectric material having a dielectric constant (k) less than about 2.6, such as from 2.5 to 2.2. In some embodiments, ELK dielectric materials include carbon-doped silicon oxide, amorphous fluorinated carbon, parylene, bis-benzocyclobutenes (BCB), polytetrafluoroethylene (PTFE) (Teflon), or silicon oxycarbide polymers (SiOC). In some embodiments, ELK dielectric materials may include porous versions of existing dielectric material, such as porous hydrogen silsesquioxane (HSQ), porous methyl silsesquioxane (MSQ), porous polyarylether (PAE), porous SILK, or porous SiO2. The IMD layers may be formed by any suitable deposition process. In some embodiments, the IMD layers may be deposited by a PECVD process or by a spin coating process.

The metal features may include wires, lines and via structures. The metal features may be formed of any suitable electrically conductive material, such as tungsten (W), copper (Cu), a copper alloy, aluminum (Al), an aluminum alloy, silver, gold, combinations thereof, or the like. Other suitable electrically conductive materials, e.g., conductive nitride compounds, are also possible and within the scope of disclosure.

In some implementations, the conductive features 220 (220a, 220c) are formed as a part of the RDL levels 312 over the lower metallization levels 310. The RDL levels 310 may include 2-4 layers of metal traces and have a pitch of, e.g., 720 nm. Other configurations or pitches of the RDL levels 312 are also possible and included in the disclosure. Each of the conductive features 220 may include a same conductive material of the respective metallization level, e.g., copper, aluminum, silver or gold. For example, the conductive features 220 may be copper at an atomic percentage greater than 80%, such as greater than 90% or greater than 95%, although greater or lesser percentages may be used.

In some embodiments, the conductive features 220 may be formed by a dual-Damascene process or by multiple single Damascene processes. Single-Damascene processes generally form and fill a single feature with a metal material, e.g., copper, per Damascene stage. Dual-Damascene processes generally form and fill two features with copper at once, e.g., a trench and overlapping through-hole may both be filled with a single copper deposition using dual-Damascene processes. In some embodiments, the conductive features 220 may be formed by an electroplating process.

For example, the Damascene processes may include patterning the dielectric layers, e.g., the IMD layers, to form openings, such as trenches and/or though-holes, e.g., via holes. A deposition process may be performed to deposit a conductive metal, e.g., copper, in the openings. A planarization process, such as chemical-mechanical planarization (CMP) may then be performed to remove excess metal, e.g., copper.

For example, the patterning, metal deposition, and planarizing processes may be performed for each of the dielectric layers, e.g., the IMD layers, in order to form the conductive features 220.

In some embodiments, barrier layers (not shown) may be disposed between the dielectric layers and the conductive features 220 to prevent unwanted metal diffusion. The barrier layer may include Ta, TaN, Ti, TiN, CoW, or combinations thereof, for example. Other suitable barrier layer materials are within the contemplated scope of disclosure.

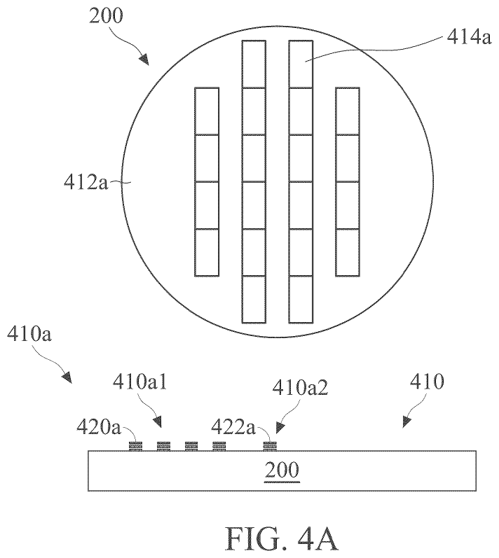

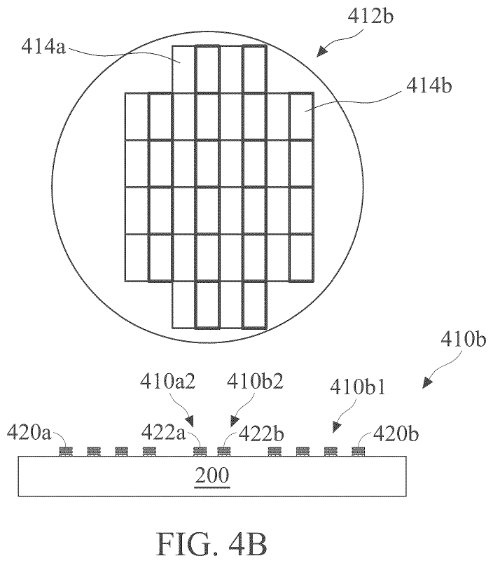

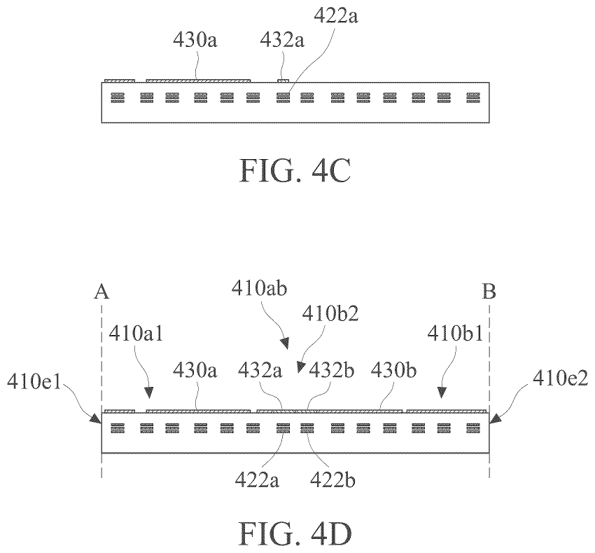

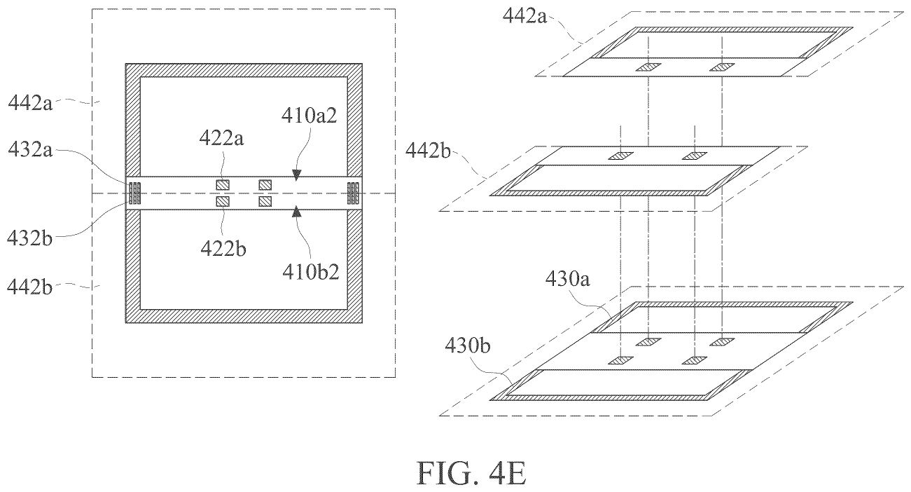

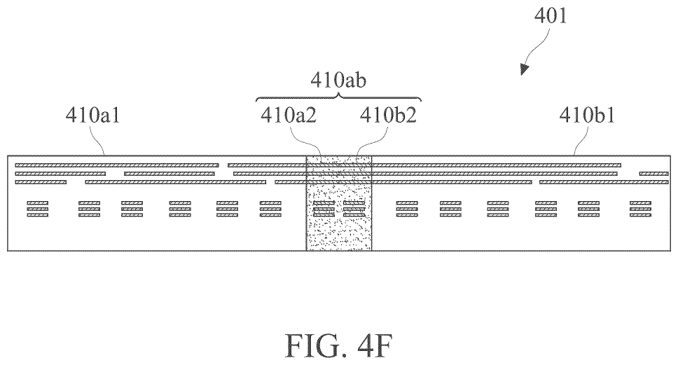

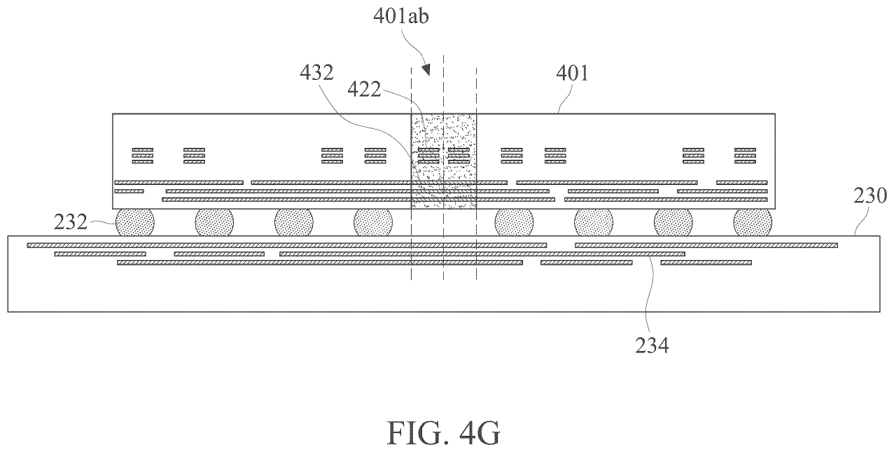

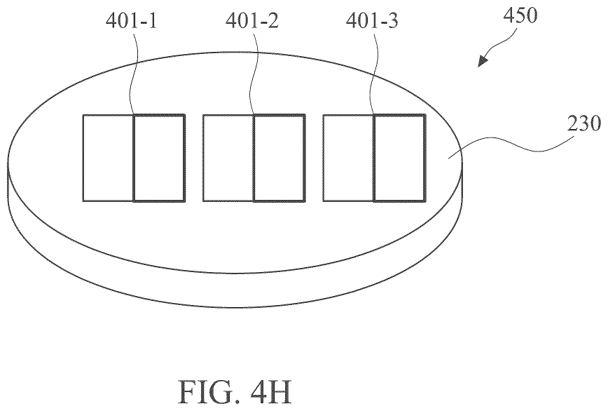

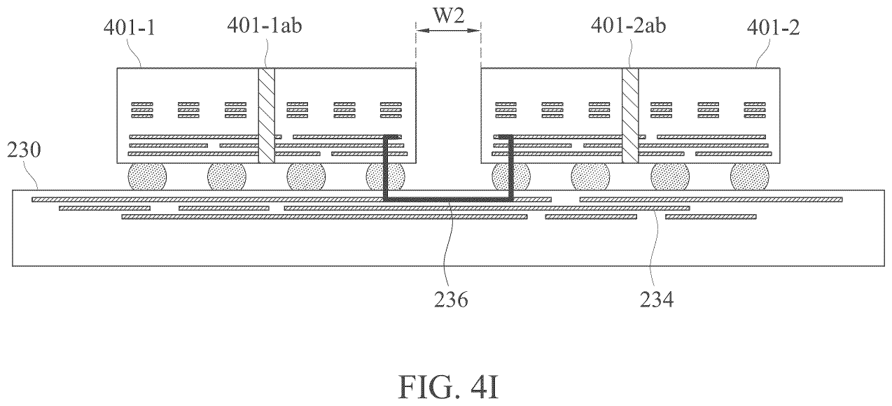

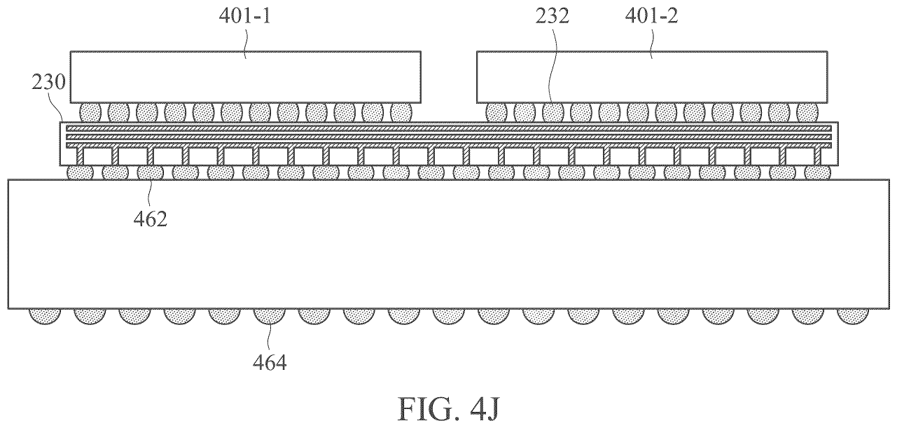

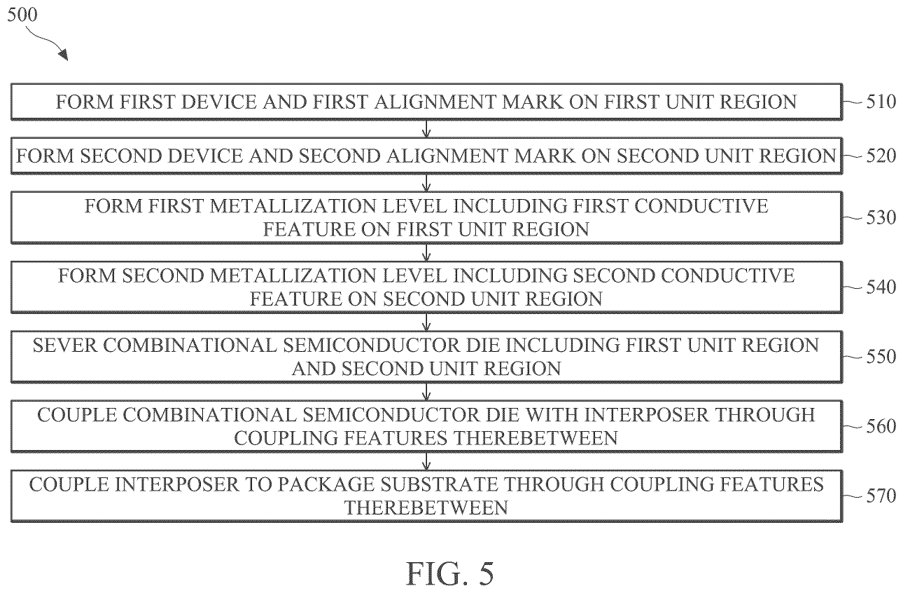

FIGS. 4A-4J representatively illustrate semiconductor structures at different stages of a fabrication process of forming a semiconductor package structure including a combinational semiconductor die. FIG. 5 shows an example fabrication process. In the example shown in FIGS. 4A-4J, an example combinational semiconductor die includes two unit regions adjacent to one another for illustrative purposes. It should be appreciated that similar fabrication process can be used to make a combinational semiconductor die having more than two unit regions. Referring to FIG. 5 with reference also to FIG. 4A, in processing operation 510, devices 420a and alignment marks 422a are formed on first unit regions 410a on a wafer 200. FIG. 4A shows a wafer 200 from a top view and a combinational semiconductor die 410 on the wafer 200 from a cross-sectional view. For example, the forming the first devices 420a includes a first light-exposure procedure through a first lithography mask 412a. The first lithography mask 412a is placed so as to expose (e.g., directly over) only a portion of photoresist on the first unit regions 410a on the wafer 400, which include the spaces for the relevant dummy portions 410a2. First lithography mask 412a, limited by the maximum size of its reticle field, does not to cover both a first unit region 410a and an adjacent second unit region 410b. Rather, the first lithography mask 412a is used to expose portions of a photoresist only on the first unit region 410a including the relevant dummy portions. The first light-exposure is performed to expose photoresist portions through mask openings 414a, with remaining portions of the photoresist not being exposed.

In some implementations, the alignment marks 422a are formed in the dummy portion 410a2 of the unit region 410a.

In operation 520, with reference also to FIG. 4B, devices 420b and alignment marks 422b are formed on second unit regions 410b on the wafer 400. The operation 520 includes a second light-exposure through a second lithography mask 412b. The second lithography mask 412b is placed so as to expose (e.g., directly over) the second unit region 410b including the relevant dummy portions 410b2. The second lithography mask 412b is used to expose portions of the photoresist on the second unit regions 410b including relevant dummy portions 410b2, but not the first unit region 410a. The second lithography mask 412b is so placed such that the exposed photoresist portions in the second unit regions 410b abut those of the first unit regions 410a. Specifically, the dummy portions 410b2 are exposed to be in direct contact with or abut the corresponding dummy portions 410a2. The second light-exposure in the operation 520 is then performed to expose the photoresist portion on the second unit regions 410b through mask openings 414b on the second lithography mask 412b. In FIG. 4B, openings 414a of the first mask 412a are shown to illustrate the relative positions of the openings 414a of the first mask 412a with respect to the openings 414b of the second mask 412b, for illustrative purposes only. It is appreciated that the second mask 412b does not include openings 414a.

In some implementations, the alignment marks 422b are formed in the dummy portion 410b2 of the unit region 410b. The alignment marks 422a, 422b function to facilitate that, among others, conductive features formed on the dummy portions 410a2, 410b2 are aligned to one another so that conductive features in the dummy portions 410a2, 410b2 are joined or stitched together. In some implementations, an alignment marks 422a may be aligned to a corresponding alignment mark 422b. In some implementations, an alignment mark 422a may offset from a corresponding alignment mark 422b in a predetermined manner.

It should be noted that the forming of the device 420a or the device 420b each may involve multiple photoresists and exposures using multiple masks. The descriptions about masks 412a, 412b, and the related exposures may apply to each of the photoresists and exposures used in the formation of devices 420a, 420b.

In operation 530, with reference also to FIG. 4C, a metallization level 430a is formed on the unit region 410a. The metallization level 430a includes conductive features 432a in the dummy portion 410a2. In some implementations, the metallization level 430a including the conductive features 432a is formed as or at the redistribution level RDL of the to be formed combinational semiconductor die. For example, the metallization level 430a including the conductive features 432a is formed adjacent to a surface of the to be formed combinational semiconductor die that is configured to be coupled to an interposer 230 (or a carrier substrate) through coupling features like solder bumps 232. For example, the metallization level 430a is located above the BEOL metallization levels and the interconnect structures there between. The metallization level 430a is also located above a metal pad, if any.

The metallization level 430a as a RDL layer may be formed using a polymer process or a metal damascene process. For example, in the polymer process, the passivation layer may be an organic material.

In operation 540, with reference also to FIG. 4D, a metallization level 430b is formed on the unit region 410b. The metallization level 430b includes conductive features 432b in the dummy portion 410b2. The conductive features 432b are each in direct physical contact with a corresponding conductive feature 432a such that dummy portions 410a2 and 410b2 are joined or stitched together and become stitching zones 410ab. The alignment marks 422a, 422b function to facilitate that the conductive features 432b are each aligned to and in direct physical contact with a corresponding conductive feature 432a and the features 432a are each aligned to and in direct physical contact with a corresponding conductive feature 432b.

As shown in FIG. 4E, similar to the formation of devices 420a, 420b, the formation of metallization levels 430a, 430b also use separate masks 442a, 442b, respectively. FIG. 4E shows, in both a top view and in a perspective view, that the masks 442a, 442b includes openings for respective alignment marks 422a, 422b, which help to align conductive features 432a, 432b in the formed dummy portions 410a2, 410b2 so that the corresponding conductive features 432a, 432b are in physical contact with one another.

It should be appreciated that each of the metallization levels may require multiple masks and exposures to form the features thereon. The descriptions of masks 442a, 442b are applicable to each of such masks and exposures, which are all included in the scope of the disclosure.

It also should be appreciated that although the descriptions herein provide an example that the masks, e.g., 442a, 442b, for the unit regions 410a, 410b corresponds to exposures in respective unit regions 410a, 410b that boarder and in contact with one another, such example does not limit the scope of the disclosure. In some alternative or additional implementations, the separate masks 442a, 442b may each overlap photoresist for a corresponding unit region 410a, 410b, and for a bordering portion of the adjacent unit region 410b, 410a, respectively. For example, the mask 442a may overlap and pattern photoresist on the dummy portion 410b2 of the unit region 410b that is adjacent to the unit region 410a. The mask 442b may overlap and pattern photoresist on the dummy portion 410a2 of the unit region 410a that is adjacent to the unit region 410b. That is, the photoresist on the stitching zone 410ab may experience dual exposure through both the mask 442a and the mask 442b, sequentially.

In some alternative or additional implementations, the photoresist on the stitching zone 410ab maybe exposed using one of the masks 442a or 442b. For example, the mask 442a may have openings to expose the portion of photoresist on unit region 410a and on the stitching zone 410ab including the dummy portion 410a2 of the unit region 410a and the dummy portion 410b2 of the unit region 410b. The mask 442b may only overlap and expose the portion of the photoresist on the device portion 410b1 of the unit region 410b.

In operation 550, with reference also to FIG. 4F, the combinational semiconductor die 401 is severed from the wafer 400. For example, the die 401 is severed along, among others, scribe lines A and B (FIG. 4D). The scribe lines A and B are each along an edge of a unit region different from those of the dummy portion. The combinational semiconductor die 401 includes device regions 410a1, 410b1, and a stitching zone 410ab between the device regions, all as part of a single die. The stitching zone 410ab includes a dummy portion 410a2 of unit region 410a and a dummy portion 410b2 of unit region 410b.

In operation 560, with reference also to FIG. 4G, the combinational semiconductor die 401 is coupled to an interposer 230. As shown in FIG. 4G, the combinational semiconductor die 401 is mounted on the interposer 230 The interposer 230 may include a suitable material, such as a semiconductor material (e.g., a silicon substrate), a ceramic material, an organic material (e.g., a polymer and/or thermoplastic material), a glass material, combinations thereof, etc. Other suitable substrate materials are within the contemplated scope of this disclosure. In various embodiments, the interposer 230 may include a redistribution structure or redistribution layers 234. The redistribution layers 234 may be electrically coupled to one or more of the coupling features 232 between the combinational semiconductor die 401 and the interposer 230.

The interposer 230 may be an organic interposer or may be a silicon interposer, which are all included in the scope of the disclosure.

The combinational semiconductor die 401 may be electrically coupled to the interposer 230 via a plurality of coupling features, e.g., solder bumps 232, that connect respective bonding pads or micro-bumps (not specifically shown) of the combinational semiconductor die 401 and the interposer 230. The redistribution interconnect structure 234 may be configured to electrically couple to the combinational semiconductor dies 401 to allow signal propagation between the combinational semiconductor dies 401 and the interposer 230 and/or other dies or substrates coupled to the interposer 230.

Given that the combinational semiconductor die 401 includes the stitching zone 401ab having conductive features 432 (432a, 432b) that connect to one another, the device in the unit region 410a and the device in the unit region 410b can be connected to one another for signal propagation therebetween using the conductive features 432. As such, the devices in the combinational semiconductor die 401 may not rely on interconnection through the RDL layers 234 of the interposer 230 for signal propagation therebetween.

Referring to FIG. 4H, a plurality of combinational semiconductor dies 401 (401-1, 401-2, and 401-3 shown) may be mounted on the interposer 230. According to various embodiments, a semiconductor device or package 450 may include a plurality of integrated circuit (IC) semiconductor dies including a plurality of combinational semiconductor dies 401 and/or other semiconductor dies (not specifically shown for brevity) on the interposer 230. In various implementations, each of the combinational dies or other semiconductor dies may be configured as a three-dimensional device, such as a three-dimensional integrated circuit (3DICs), a system-on-chip (SOC) device, or a system-on-integrated-circuit (SoIC) device. The other semiconductor dies may be an integrated circuit IC device die or an integrated passive device die IPD or other components.

Referring to FIG. 4I, in some implementations, two combinational semiconductor dies 401-1 and 401-2 may be positioned adjacent to one another on the interposer 230. Due to the physical limitations in handling dies, there is a distance W2 between the two combinational semiconductor dies 401-1 and 401-2. In some implementations, the distance W2 is in a range of 40 μm to 300 μm. The redistribution structure 236 may include a portion 236 configured to electrically couple combinational semiconductor dies 401-1 and 401-2 to one another and to allow signal propagation between devices in combinational semiconductor dies 401-1 and 401-2. Devices within each or the combinational semiconductor dies 401-1, 401-2 can be connected through the respective stitching zones 401-1ab, 401-2ab, respectively.

In operation 570, with reference also top FIG. 4J, the interposer 230, having combinational semiconductor dies 401-1, 401-2 coupled thereon, is coupled to a package substrate 460. As shown in FIG. 4J, the interposer 230 may be coupled to the package substrate 460 through coupling features like solder bumps 462. The package substrate 460 may further be electrically coupled to a printed circuit board (PCB) (not shown) via coupling features, e.g., solder balls 464. that connect respective bump structures of the package substrate 460 and the PCB.

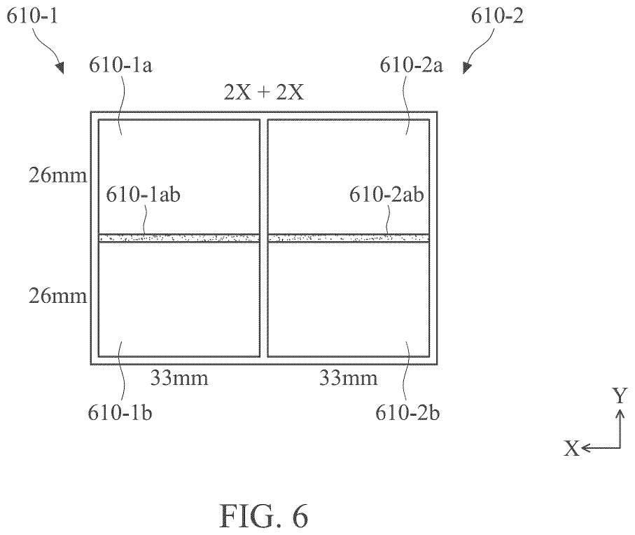

FIG. 6 shows an implementation that in each combinational die 610-1, 610-2, the unit regions 610-1a, 610-1b, 610-2a, 610-2b are arranged with respect to the adjacent unit region along the y-axis direction, and the two combinational dies 610-1, 610-2 are arranged with respect to one another in the X-axis direction different from the y-axis direction.

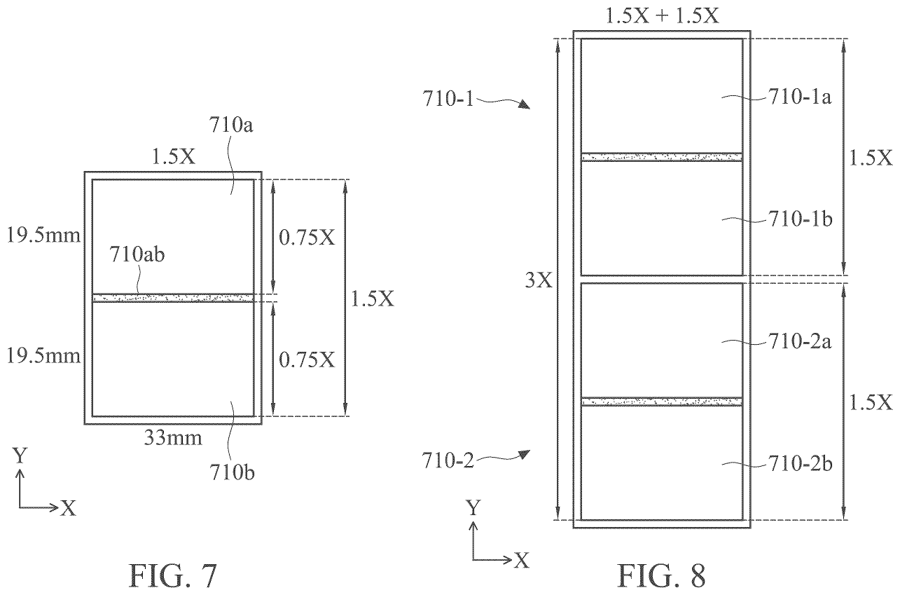

FIG. 7 shows that a unit region 710a, 710b may include a size that is not the full reticle size limitation. For example, the unit regions 710a, 710b may be formed using masks that overlap one another in the y-axis direction so that each unit regions 710a, 710b includes a dimension of full reticle size, e.g., 33 mm, in the X-axis direction, and includes a dimension of 0.75 of full reticle size, e.g., 0.75×26 mm=19.5 mm, in the Y-axis direction.

FIG. 8 shows an implementation that in each combinational die 710-1, 710-2, the unit regions 710-1a, 710-1b, 710-2a, 710-2b are arranged with respect to the adjacent unit region along the y-axis direction, and the two combinational dies 710-1, 710-2 are also arranged with respect to one another in the Y-axis direction.

Described embodiments of the subject matter can include one or more features, alone or in combination. For example, in a first embodiment a method of manufacturing a semiconductor device includes forming a first unit region over a semiconductor substrate using a first mask, the first unit region including a first device portion and a first dummy portion, the first dummy portion including a first alignment mark; forming a second unit region over the semiconductor substrate using a second mask separate from the first mask, the second unit region including a second device portion and a second dummy portion, the second dummy portion adjacent to the first dummy portion, the second dummy portion including a second alignment mark corresponding to the first alignment mark; and forming a single first die including the first unit region and the second unit region together.

In a second embodiment, a method of manufacturing a semiconductor device includes: forming a first unit region over a semiconductor substrate using a first mask, the first unit region including a first device portion and a first dummy portion, the first unit region including a size of a reticle size limitation; forming a second unit region over the semiconductor substrate using a second mask, the second unit region including a second device portion and a second dummy portion, the second dummy portion in physical contact with the first dummy portion, the second unit region including the size of the reticle size limitation; and forming a single first die that includes the first unit region and the second unit region together.

In a third embodiment, a structure includes: a combinational semiconductor die, the combinational semiconductor die including a first unit region and a second unit region over a semiconductor substrate, the first unit region abutting the second unit region, the first unit region including a first device portion and a first dummy portion, the second unit region including a second device portion and a second dummy portion, the first dummy portion including a first conductive feature, the second dummy portion including a second conductive feature in connection with the first conductive feature; an interposer; and solder bumps coupled between the combinational semiconductor die and the interposer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor device comprising:
forming a first unit region over a semiconductor substrate using a first mask, the first unit region including a first device portion and a first dummy portion, the first dummy portion including a first alignment mark;
forming a second unit region over the semiconductor substrate using a second mask separate from the first mask, the second unit region including a second device portion and a second dummy portion, the second dummy portion adjacent to the first dummy portion, the second dummy portion including a second alignment mark corresponding to the first alignment mark; and
forming a single first die including the first unit region and the second unit region together.

2. The method of claim 1, wherein the first dummy portion abuts the second dummy portion.

3. The method of claim 1, wherein the first dummy portion includes a first conductive feature in a redistribution level of metallization, the second dummy portion includes a second conductive feature in the redistribution level of metallization, and the second conductive feature is in contact with the first conductive feature.

4. The method of claim 3, further comprising coupling the first die to an interposer, wherein the first conductive feature and the second conductive feature are each closer to the interposer than the semiconductor substrate.

5. The method of claim 4, wherein the first die is coupled to the interposer through coupling features positioned between the first die and the interposer, and
wherein the interposer includes a redistribution structure electrically coupled to the coupling features.

6. The method of claim 5, comprising coupling a second die to the interposer, the second die being separated from the first die by a distance,
wherein the first die is connected to the second die through a first portion of the redistribution structure of the interposer.

7. The method of claim 3, wherein the first conductive feature is formed in a redistribution layer in the first unit region.

8. The method of claim 1, wherein the first mask is used to expose a first photoresist portion on the first unit region, and the second mask is used to expose a second photoresist portion on the second unit region.

9. The method of claim 1, wherein the first unit region and the second unit region each has a size of about 33 mm×26 mm.

10. The method of claim 9, wherein the first die has a size of about 33 mm×52 mm.

11. The method of claim 9, wherein the first die has a size of about 66 mm×26 mm.

12. The method of claim 1, wherein first dummy portion has a dimension in a range from about 5 μm to about 20 μm, inclusive, along a direction between the first unit region and the second unit region.

13. A method of manufacturing a semiconductor device comprising:
forming a first unit region over a semiconductor substrate using a first mask, the first unit region including a first device portion and a first dummy portion, the first unit region including a size of a reticle size limitation;
forming a second unit region over the semiconductor substrate using a second mask, the second unit region including a second device portion and a second dummy portion, the second dummy portion in physical contact with the first dummy portion, the second unit region including the size of the reticle size limitation; and
forming a single first die that includes the first unit region and the second unit region together.

14. The method of claim 13, wherein the first unit region includes a first side of 26 mm and a second side of 33 mm, the second unit region includes a first side of 26 mm and a second side of 33 mm, and the first side of the first unit region is in physical contact with the first side of the second unit region.

15. The method of claim 13, wherein the first unit region includes a first side of 26 mm and a second side of 33 mm, the second unit region includes a first side of 26 mm and a second side of 33 mm, and the second side of the first unit region is in physical contact with the second side of the second unit region.

16. The method of claim 13, wherein the first dummy portion includes a first conductive feature, the second dummy portion includes a second conductive feature, and the second conductive feature is in physical contact with the first conductive feature.

17. The method of claim 13, wherein the first dummy portion includes a first alignment feature, the second dummy portion includes a second alignment feature, and the second alignment feature corresponds to the first alignment feature.

18. A structure comprising:
a combinational semiconductor die, the combinational semiconductor die including a first unit region and a second unit region over a semiconductor substrate, the first unit region abutting the second unit region, the first unit region including a first device portion and a first dummy portion, the second unit region including a second device portion and a second dummy portion, the first dummy portion including a first conductive feature, the second dummy portion including a second conductive feature in connection with the first conductive feature;
an interposer; and
solder bumps coupled between the combinational semiconductor die and the interposer.

19. The structure of claim 18, wherein the first device portion includes a first graphics processing unit and the second device portion includes a second graphics processing unit.

20. The structure of claim 18, wherein the first unit region and the second unit region each includes a size of a reticle size limitation.
